(19) United States
(12) Patent Application Publication
(10) Pub. No.: US 2016/0233275 A1
(43) Pub. Date: Aug. 11, 2016

(54) ORGANIC EL DISPLAY DEVICE

(71) Applicant: Japan Display Inc., Tokyo (JP)

(72) Inventor: Hironori TOYODA, Tokyo (JP)

(21) Appl. No.: 15/017,213

(22) Filed: Feb. 5, 2016

(30) Foreign Application Priority Data
Feb. 10, 2015 (JP) 2015-023885

(51) Int. Cl. H01L 27/32; H01L 51/52; H01L 51/00; H01L 51/50

(52) U.S. Cl. CPC H01L 27/3232; H01L 51/504; H01L 51/5271; H01L 51/005; H01L 51/0072; H01L 51/0067; H01L 51/0073; H01L 2251/301

(57) ABSTRACT

Provided is an organic EL display device which includes an insulating surface, an anode electrode formed over the insulating surface, an organic layer formed over the anode electrode; a cathode electrode formed over the organic layer; and a photochromic layer in contact with the cathode electrode or the anode electrode, where the photochromic layer has a light-absorbing property with respect to a specific wavelength region.

### CROSS REFERENCE TO RELATED APPLICATIONS

This application is based on and claims the benefit of priority from the prior Japanese Patent Application No. 2015-023885, filed on 10 Feb. 2015, the entire contents of which are incorporate herein by reference.

### FIELD

The present invention relates to an organic EL display device. In particular, the present invention relates to technology of an organic EL element in which a photochromic layer is arranged.

### BACKGROUND

Recently, it has been strongly demanded to increase resolution and decrease power consumption of light-emitting display devices for mobile use. As the display devices for mobile use, liquid crystal display devices (LCD), display devices utilizing self-emitting elements such as organic EL display devices (OLED), electronic paper, and the like are represented.

Among them, the organic EL display devices have been developed for the purpose of reducing thickness, increasing luminance, and improving response speed of display panels. The organic EL display devices are display devices having pixels composed of OLED and characterized by high response speed due to the absence of mechanical operation. The organic EL display devices do not require a backlight source and a polarizing plate because each pixel undergoes self-emission, which allows for the reduction in thickness of the display devices. Therefore, the organic EL display devices are expected as next generation display devices.

The OLED element decreases in emission efficiency while a current flows, and it has been known that a phenomenon called “burning” takes place due to the reduction in luminance at a certain current. In particular, in the case of a white-emissive OLED element having a tandem structure including a blue-emissive (B) OLED element and a yellow-emissive (Y) OLED element, a change of the balance of the emission intensity of B and Y causes a variation of the chromaticity, which may result in the burning phenomenon.

An organic EL display device arranged with a photochromic layer was proposed in order to sufficiently demonstrate a function of the organic EL display as a transparent display (e.g., Japanese laid- open publication No. 2014-72126).

### SUMMARY

An organic EL display device according to an embodiment of the present invention includes an insulating surface; an anode electrode provided over the insulating surface; an organic layer provided over the anode electrode; and a cathode electrode over the organic layer. The organic EL display device further includes a photochromic layer which is provided so as to be in contact with the cathode electrode or the anode electrode and which has a light-absorption property with respect to a specific wavelength region.

### BRIEF DESCRIPTION OF DRAWINGS

FIG. 1 is a drawing showing the whole structure of an organic EL display device according to Embodiment 1 of the present invention;

FIG. 2 is a drawing showing a structure of a pixel portion of an organic EL display device according to Embodiment 1 of the present invention;

FIG. 3 is a cross-sectional view of an organic EL display device according to Embodiment 1 of the present invention;

FIG. 4 is a schematic view of a cross section of an organic EL display device according to Embodiment 1 of the present invention;

FIG. 5A is a graph explaining a characteristic of a photochromic layer of an organic EL display device according to Embodiment 1 of the present invention;

FIGS. 5B and FIG. 5C are graphs explaining a change in relative luminance of an organic EL display device according to Embodiment 1 of the present invention;

FIG. 6A to FIG. 6C are drawings explaining a driving method of an organic EL display device according to Embodiment 1 of the present invention;

FIG. 7 is a cross-sectional view of an organic EL display device according to Embodiment 2 of the present invention;

FIG. 8 is a schematic view of a cross section of an organic EL display device according to Embodiment 2 of the present invention;

FIG. 9 is a schematic view of a cross section of an organic EL display device according to Embodiment 3 of the present invention; and

FIG. 10 is a schematic view of a layout of a light-emitting layer and a photochromic layer of an organic EL display device according to Embodiment 4 of the present invention.

### DESCRIPTION OF EMBODIMENTS

An object of the present invention is to suppress the variation of chromaticity when a current flows in an organic EL element in order to prevent burning of an organic EL display device.

Hereinafter, the embodiments of the present invention are explained with reference to the drawings. Note that the disclosure is only an example of the embodiments, and those readily conceived by persons skilled in the art through an appropriate change of the embodiments within the concept of the invention should be considered to be included in the scope of the present invention. Further, the width, thickness, shape, and the like of each component may be schematically illustrated and different from those of an actual mode in the drawings in order to provide a more clear explanation. However, the drawings simply give an example and do not limit the interpretation of the present invention. Moreover, in the specification and each of the drawings, elements which are the same as those explained in the preceding drawings are denoted with the same reference numbers, and there detailed explanation may be omitted appropriately.

### Embodiment 1

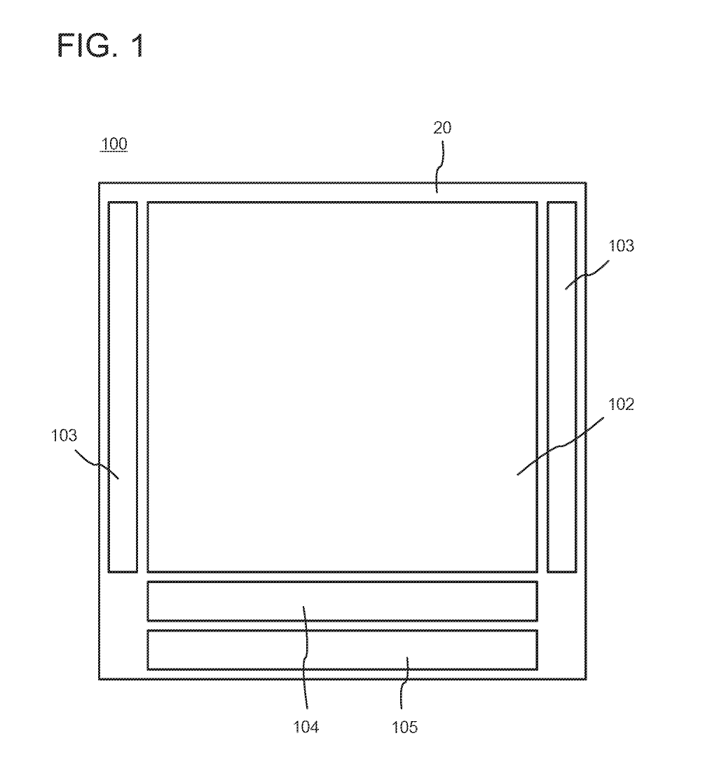

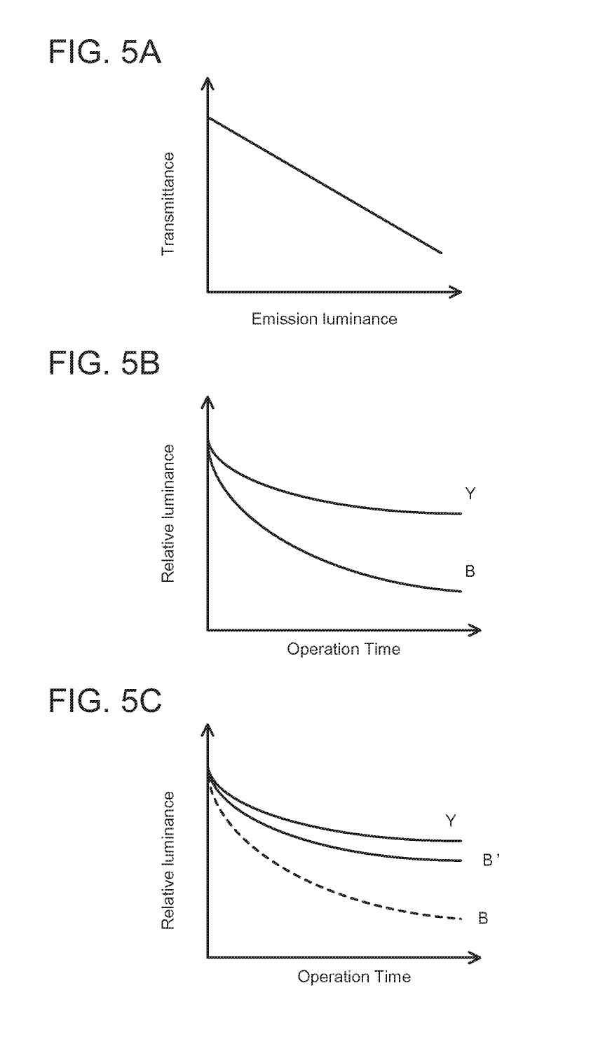

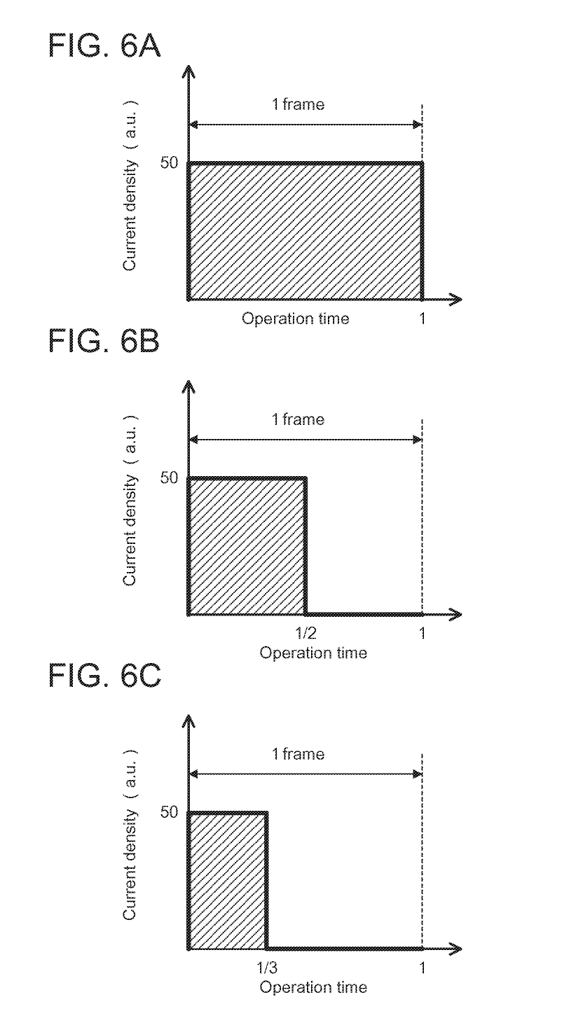

A structure of an organic EL display device according to Embodiment 1 is explained using FIG. 1 to FIG. 4, FIG. 5A to FIG. 5C, and FIG. 6A to FIG. 6C.

### <Whole Structure of Organic EL Display Device>

FIG. 1 is a drawing showing the whole structure of the organic EL display device 100 according to Embodiment 1 of the present invention. The organic EL display device 100 has a pixel portion (display region) 102, a scanning line driving circuit 103, a data line driving circuit 104, and a driver IC 105 formed over a substrate 20.

The driver IC 105 functions as a control portion giving signals to the scanning line driving circuit 103 and the data line driving circuit 104.

Note that the data line driving circuit 104 may also be included in the driver IC 105. In FIG. 1, an example in which the driver IC 105 is integrated over the substrate 20 is shown. However, the driver IC 105 may also be separately arranged over another substrate in a form of an IC chip. Additionally, a mode in which the driver IC 105 is mounted to an FPC (Flexible Printed Circuit) and attached to the substrate may be employed.

A plurality of pixels are arranged in a matrix form in the pixel portion 102 shown in FIG. 1. Data signals corresponding to image data are provided to each of the pixels from the data line driving circuit 104. The data signals are provided to pixel electrodes through transistors formed in each of the pixels, by which display can be performed according to the image data. Typically, a thin film transistor (TFT) can be used as the transistors. However, the transistors are not limited to a TFT, and any kind of element can be used as long as a current flow can be controlled.

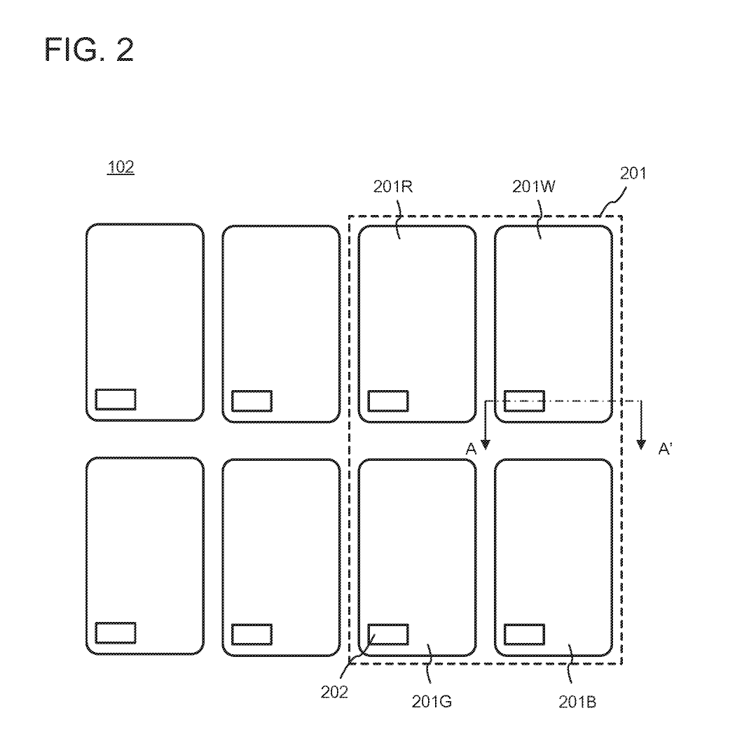

FIG. 2 is a drawing showing a structure of the pixel portion 102 of the organic EL display device 100 illustrated in FIG. 1. In this embodiment, the pixel 201 includes a sub-pixel 201R corresponding to red (R), a sub-pixel 201G corresponding to green (G), a sub-pixel 201B corresponding to blue (B), and a sub-pixel 201W corresponding to white (W). A thin film transistor 202 is provided as a switching element in each of the sub-pixels. On/off control of each of the sub-pixels 201R, 201G, 201B, and 201W by using the thin film transistor 202 allows light emission in an arbitrary color corresponding to each of the sub-pixels, by which a variety of colors can be reproduced in one pixel.

A structure using sub-pixels of 4 colors of RGBW is shown in FIG. 2. However, this embodiment is not limited to this structure and may employ a structure in which a sub-pixel corresponding to yellow (Y) is used instead of the sub-pixel corresponding to W or a structure in which only 3 sub-pixels corresponding to the primary colors RGB are used in the absence of the sub-pixel corresponding to W. Additionally, although an example in which the sub-pixels corresponding to the same color are arranged in a stripe layout is shown, another layout which achieves the delta layout, the Bayer layout, or the PenTile layout can be adopted.

### <Cross-Sectional Structure of Organic EL Display Device>

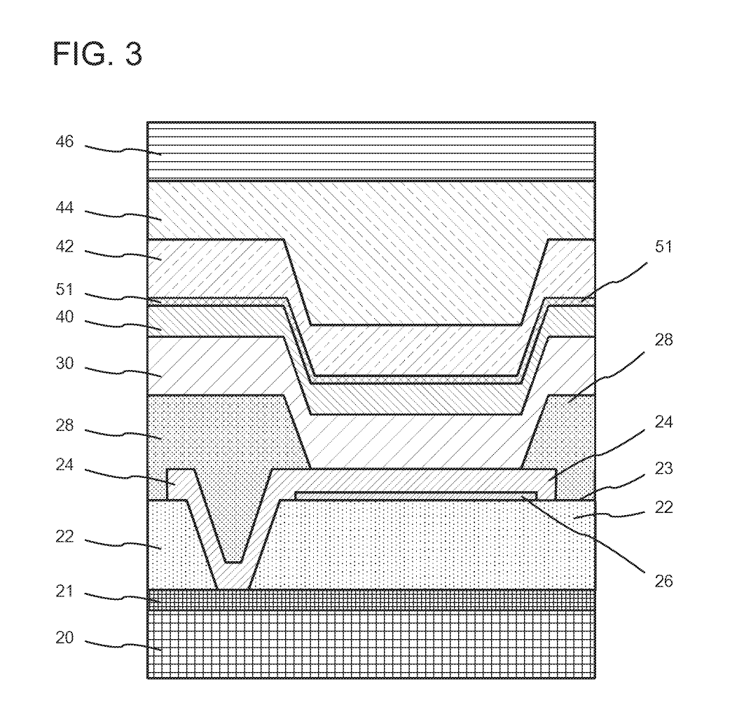

Next, a cross-sectional structure of the organic EL display device according to Embodiment 1 is explained using FIG. 3.

FIG. 3 shows a cross-sectional view of the pixel of the organic EL display device according to Embodiment 1 and corresponds to the cross-section obtained by cutting the pixel illustrated in FIG. 2 along the A-A′ line. The substrate 20 is formed using glass, a resin, and the like. A pixel circuit layer 21 composed of a control TFT, a driving TFT, a storage capacitor, and the like is arranged over the substrate 20. The pixel circuit layer 21 includes an interlayer insulating film in which a plurality of layers formed with an inorganic material such as silicon nitride and silicon oxide are stacked. Further, in addition to the pixel circuit layer 21, a scanning signal line, an image signal line, a driving power source line, an auxiliary capacitor electrode, and the like are appropriately arranged over the substrate 20. A planarizing film 22 formed with an organic material such as an acrylic resin and a polyimide is formed on an upper side of the interlayer insulating film for planarization, resulting in an insulating surface 23 at an upper surface of the planarization film 22.

An anode electrode 24 corresponding to an anode is arranged over the insulating surface 23. The anode electrode 24 is also arranged in a contact hole formed in the planarization film 22, thereby electrically connecting the anode electrode 24 to the pixel circuit. A material with a light-transmitting property may be used for the anode electrode 24. For example, ITO (indium tin oxide), ZnO (zinc oxide), SnO₂ (tin oxide), In₂O₃ (indium oxide), IZO (zinc oxide added with indium as a dopant), GZO (zinc oxide added with gallium as a dopant), AZO (zinc oxide added with aluminum as a dopant), titanium oxide added with an impurity such as niobium as a dopant, and the like can be used. A reflective metal 26 having a light-reflecting property such as Al, Ti, Mo, Ni, Ag, and their alloys is arranged in a portion corresponding to the pixel under the anode electrode 24 (on a side of the substrate 20). In the case of the top-emission type organic EL display device shown in Embodiment 1, because the reflective metal 26 having a light-reflecting property and the anode electrode 24 having a light-transmitting property are stacked in this order, the reflective metal 26 functions as a light-reflecting electrode to reflect light, which is generated in an organic layer 30 and which is emitted downwards, upwards. Note that the aforementioned layer structure of the reflective metal 26 and the anode electrode 24 is only an example, and a three-layer structure in which an anode electrode, a reflective metal, and an anode electrode are stacked in this order over the insulating surface 23 (e.g., ITO/AG/ITO) may be used.

A pixel separation film (i.e., bank) 28 is arranged so that an edge portion of the anode electrode 24 and a contact hole formed in the planarization film 22 are covered. A common resin material can be used for the pixel separation film 28, and a photo-sensitive resin material can be also used. As a photo-sensitive resin, a photo-sensitive acrylic resin, a photo-sensitive polyimide, and the like can be used. The portion which is defined by the pixel separation film 28 of the anode electrode 24 serves as the pixel.

The organic layer 30, a cathode electrode 40, a photochromic layer 51, and a passivation layer 42 are stacked in this order over the anode electrode 24 and the pixel separation film 28. Additionally, an opposing substrate 46 is bonded to the substrate 20, and a region between the passivation layer 42 and the opposing substrate 46 is filled with a filling material 44. The organic layer 30 and the photochromic layer 51 are explained below. The cathode electrode 40 corresponds to a cathode and is a common electrode formed as a single film to supply electric power to the organic layer 30 in association with the anode electrode 24. A material having a light-transmitting property can be used for the cathode electrode 40. Similar to the anode electrode 24, ITO, ZnO, SnO₂, In₂O₃, IGO, GZO, AZO, titanium oxide added with an impurity such as Nb as a dopant, and the like can be used as a material having a light-transmitting property.

The passivation layer 42 is arranged so that at least the organic layer 30 is covered, and the passivation layer 42 can be formed using a material having a high ability to block an impurity such as water. For example, a SiNₓ film, a SiOₓ film, a SiNₓO_{y} film, a SiOₓN_{y} film, an AlNₓ film, an AlOₓ film, an AlOₓN_{y} film, and the like can be used (x and y are arbitrary). Further, a structure in which these films are stacked can be employed.

A common transparent resin is used for the filling material 44. The filling material 44 relieves the steps resulted from the structures formed over the substrate 20 and the opposing substrate 46 which is bonded to the substrate 20 so as to face each other. The region between the substrate 20 and the opposing substrate 46 is filled with the filling material 44 so that these substrates are arranged to be substantially parallel to each other.

### <Structure of Organic Layer>

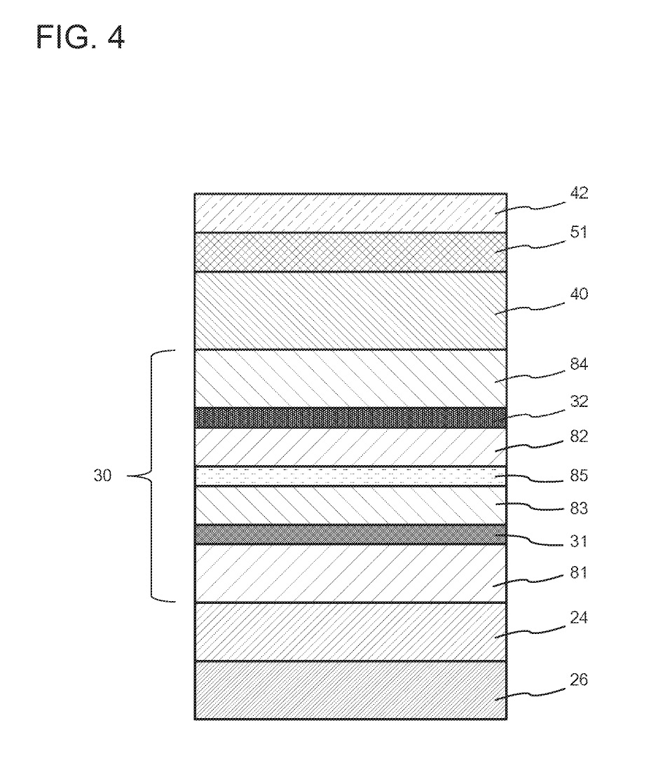

Next, the organic layer 30 of Embodiment 1 is explained using FIG. 4. FIG. 4 is a schematic view of a cross section of the organic EL display device of Embodiment 1 of the present invention and is an expanded view of a portion showing the organic layer 30 at the center.

As shown in FIG. 4, the organic layer 30 in Embodiment 1 has a tandem structure in which a Y light-emitting layer 31 that is yellow emissive and a B light-emitting layer 32 that is blue emissive are stacked. The organic layer 30 displays white color as whole by combining the yellow emission obtained from the Y light-emitting layer 31 and the blue emission obtained from the B light-emitting layer 32.

A carrier transport layer (hole transport layers 81 and 82 and electron transport layers 83 and 84), an charge generation layer 85, and the like are arranged in the organic layer 30 in addition to the Y light-emitting layer 31 and the B light-emitting layer 32. The organic layer 30 is prepared using a low molecular-weight material or a high molecular-weight material. For example, when a low molecular-weight organic material is used for organic layer 30, the carrier transport layers such as the hole transport layers 81 and 82 and the electron transport layers 83 and 84 are added in addition to the light-emitting layer including an emissive organic material, so as to sandwich the light-emitting layer. Moreover, a unit (Y unit) composed of the hole transport layer 81, the Y light-emitting layer 31, and the electron transport layer 83 and a unit (B unit) composed of the hole transport layer 82, the B light-emitting layer 32, and the electron transport layer 84 are stacked with the charge generation layer 85 interposed therebetween. The charge generation layer 85 injects electrons and holes to the Y and B units, respectively.

### <Photochromic Layer>

Next, the photochromic layer 51 in Embodiment 1 is explained with reference to FIG. 5A to FIG. 5C.

The photochromic layer 51 of Embodiment 1 is arranged over and in contact with the cathode electrode 40. An inorganic compound or an organic compound which has a light-absorbing property with respect to a specific wavelength region is used for the photochromic layer 51.

As an inorganic compound used for the photochromic layer 51, a metal oxide and the like including at least one of titanium (Ti), vanadium (V), chromium (Cr), manganese (Mn), iron (Fe), cobalt (Co), nickel (Ni), copper (Cu), zinc (Zn), niobium (Nb), molybdenum (Mo), ruthenium (Ru), indium (In), tin (Sn), antimony (Sb), tantalum (Ta), tungsten (W), rhenium (Re), osmium (Os), iridium (Ir), and biomass (Bi) is given, for example. These metal oxides are able to attain a characteristic to absorb light of a specific wavelength region due to the localized surface plasmon resonance. The wavelength of the light absorbed by the photochromic layer 51 can be adjusted according to the kind of metal, size of particle, distance between the particles, and anisotropy.

A material including any of a diarylethene compound such as stilbene, a spiropyran compound, a spiroperimidine compound, a viologen compound, and an azobenzene compound may be used as an organic compound used for the photochromic layer 51. The wavelength of the light absorbed by the photochromic layer 51 can be adjusted by adding a functional group to these organic compounds.

Moreover, the photochromic layer 51 has a property whereby its absorption increases with an increasing amount of light irradiated to the photochromic layer 51. As a result, light transmittance of the photochromic layer 51 decreases with increasing luminance of the organic EL display device. FIG. 5A is a graph showing the relationship between the luminance (w/sr) of light irradiated to the photochromic layer 51 and the light transmittance of the photochromic layer 51. Referring to FIG. 5A, it is understood that an increase in luminance leads to a decrease in transmittance and a decrease in luminance results in a decrease in transmittance.

### <Effect of Photochromic Layer>

FIG. 5B is a drawing showing the change in relative luminance of the B emission and Y emission with respect to the current flow time in the organic EL element having the B light-emitting layer and the Y light-emitting layer. In FIG. 5B, B and Y represent the changes in relative luminance of the B emission and Y emission, respectively. Here, it is assumed that the time-depending deterioration of the B light-emitting layer is larger than that of the Y light-emitting layer. In this case, after a certain current flow time, the reduction of the relative luminance of the B light-emitting layer is larger than that of the Y light-emitting layer. Accordingly, in the case of the tandem structure having the B light-emitting layer and the Y light-emitting layer arranged in the organic layer, the chromaticity shifts to the yellow side after a certain current flow time. The yellow shift of the chromaticity is likely to cause the burning phenomenon due to the chromaticity variation.

In Embodiment 1, the photochromic layer 51 which has a property to selectively absorb light in a B wavelength region (400 nm to 500 nm) is arranged over the cathode electrode 40. Because the photochromic layer 51 has a light-absorbing property in the B wavelength region, the B emission irradiated to the photochromic layer 51 is absorbed, while the Y emission is not absorbed. Furthermore, the photochromic layer 51 has a property whereby its transmittance decreases with increasing amount of light irradiated thereto and increases with a decreasing amount of light irradiated thereto. That is, the photochromic layer 51 reduces the amount of B emission passing therethrough when the luminance of the B emission is high, while increasing the amount of B emission passing therethrough when the luminance of the B emission is low. Thus, it is possible to suppress the reduction of the relative luminance of B emission passing through the photochromic layer 51 which occurs in the current flow time compared with the case where the photochromic layer 51 is not arranged.

FIG. 5C is a drawing showing the change in relative luminance of the B emission (B′ in the figure) after passing through the photochromic layer 51, in addition to the change in relative luminance of the B emission and Y emission with respect to the current flow time. Comparison of B and B′ in FIG. 5C reveals that the reduction of the relative luminance can be suppressed by allowing the emission from the light-emitting layer to pass through the photochromic layer 51 and that the variation of the property which occurs as the current flow time elapses can be decreased. As described above, the arrangement of the photochromic layer 51 enables it to suppress the variation of the balance between the B emission color and the Y emission color, prevent the burning problem caused by the chromaticity shift, and improve the reliability.

### <Driving Method>

Next, a driving method of the pixel circuit of Embodiment 1 is explained with reference to FIG. 6A to FIG. 6C.

As described above, the photochromic layer 51 in Embodiment 1 has a property whereby its transmittance decreases with an increasing amount of light irradiated thereto and increases with a decreasing amount of light irradiated thereto. Therefore, when a driving method is employed where current flowing in the organic layer is changed according to the gray scale of the emission, it is considered to be difficult to correctly reproduce the gray scale because the photochromic layer 51 changes in transmittance with the change of the emission intensity of the organic layer.

Therefore, the gray scale may be controlled by the mode in which the emission duty ratio is varied in Embodiment 1. FIG. 6A is a graph showing the relationship between the operation time and the current density when display is performed at a full gray scale. Referring to FIG. 6A, the operation is carried out at a constant current density (50 (a. u.)) in one frame. FIG. 6B and FIG. 6C are graphs showing the relationship between the operation time and the current density when display is performed at ½ and ⅓ gray scales, respectively. Comparison of FIG. 6B with FIG. 6C proves that the operation is carried out at the same current density regardless of the gray scale. Note that in the case of displaying at a ½ gray scale as shown in FIG. 6B, the operation time is a ½ frame period, and the display is controlled in an operation period that is ½ the case of displaying at a full gray scale as shown in FIG. 6A. Similarly, in the case of displaying at a ⅓ gray scale as shown in FIG. 6C, the display is controlled in an operation period that is ⅓ the case of displaying at a full gray scale.

As explained above, in Embodiment 1, the display is controlled by the driving method in which the emission duty ratio is varied while keeping the current density constant, by which the gray scale can be relatively easily represented.

### <Variation of Embodiment 1>

In Embodiment 1, explanation is given using the photochromic layer 51 having a property of selectively absorbing light in the B wavelength region (400 nm to 500 nm). However, the wavelength region of the absorbed light is not limited to the B wavelength region. For example, the time-depending change in luminance of the Y light-emitting layer 31 may be larger than that of the B light-emitting layer 32, depending on the materials of the Y light-emitting layer 31 and the B light-emitting layer 32 which constitute the organic layer 30. In this case, the photochromic layer 51 having a property of selectively absorbing light in a Y wavelength region may be arranged.

### Embodiment 2

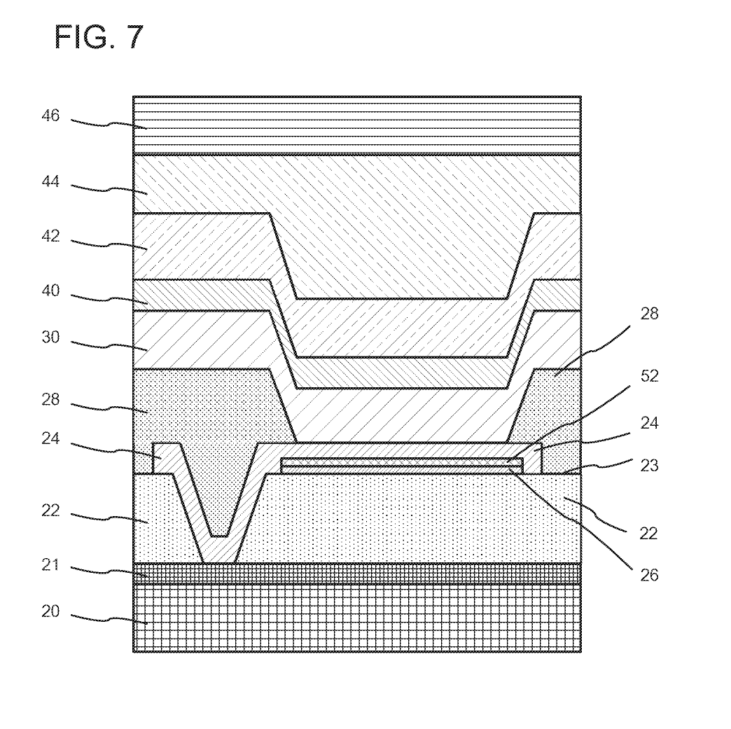

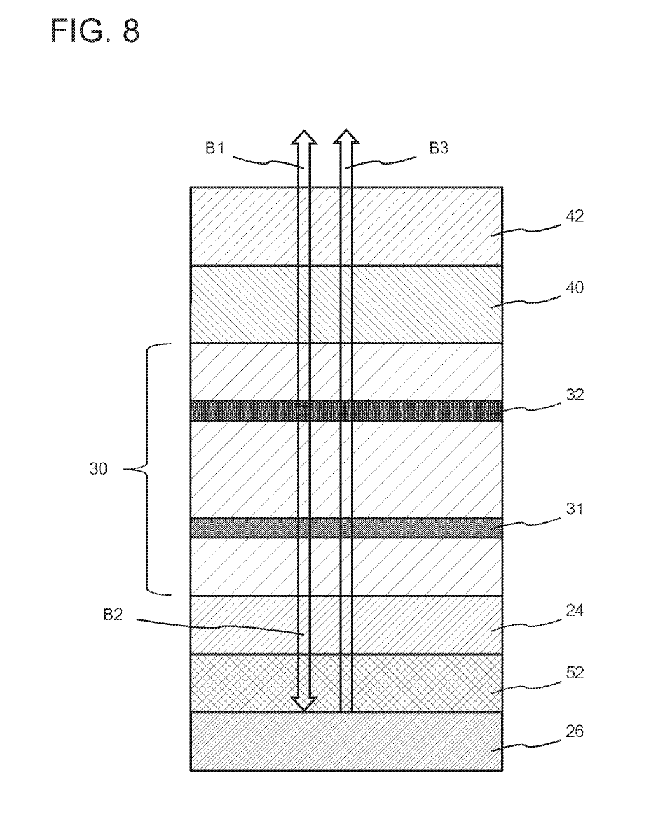

Next, the structure of the organic EL display device according to Embodiment 2 is explained using FIG. 7 and FIG. 8. Note that the portions which are not particularly specified are regarded as common to Embodiments 1 and 2.

FIG. 7 shows a cross-sectional view of the pixel of the organic EL display device according to Embodiment 2. Referring to FIG. 7, it is understood that the photochromic layer 52 is arranged between the reflective metal 26 and the anode electrode 24. Light generated in the organic layer 30 and emitted downward (to the side of the substrate 20) passes through the anode electrode 24 having a light-transmitting property and reflects upward on the reflective metal 26 having a light-reflecting property (to the side of a display surface of the display device). In Embodiment 2, part of the light generated in the light-emitting layer 30 passes through the photochromic layer 52 because the photochromic layer 52 is interposed between the anode electrode 24 and the reflective metal 26.

FIG. 8 is a schematic view of the cross section of the organic EL display device according to Embodiment 2 and is an expanded view showing the organic layer 30 at the center. In FIG. 8, B1 represents light generated in the B light-emitting layer 32 and emitted upward, B2 represents light emitted downward from the B light-emitting layer, and B3 represents light formed by the reflection of B2 on the reflective metal 26. B2 passes the photochromic layer 52 immediately before the reflection on the reflective metal 26. Further, B3 is light which passes the photochromic layer 52 immediately after the reflection on the reflective metal 26. As described above, the photochromic layer 52 has a property whereby its transmittance decreases with an increasing amount of light irradiated thereto and increases with a decreasing amount of light irradiated thereto. Thus, B3 is light which is subjected to the luminance adjustment by the photochromic layer 52.

Thus, in the organic EL display device according to Embodiment 2, the blue light passing through the passivation layer 42 from the side of the substrate 20 includes the blue light B1 that does not pass through the photochromic layer 52 and the blue light B3 that is reflected on the reflective metal 26 and then passes through the photochromic layer 52. Therefore, the arrangement of the photochromic layer 52 enables the control of the luminance of the blue light reflected on the reflective metal 26, which allows the adjustment of the luminance of the blue light component of the organic EL display device.

### <Variation of Embodiment 2>

Embodiment 2 may be an embodiment combined with Embodiment 1. That is, the photochromic layer 52 may be arranged between the reflective metal 26 and the anode electrode 24, and the photochromic layer 51 may be further arranged between the cathode electrode 40 and the passivation layer 42. In this case, the photochromic layers 51 and 52 may have a property of selectively absorbing light of the same wavelength region and also may have a property of selectively absorbing light of different wavelength regions.

### Embodiment 3

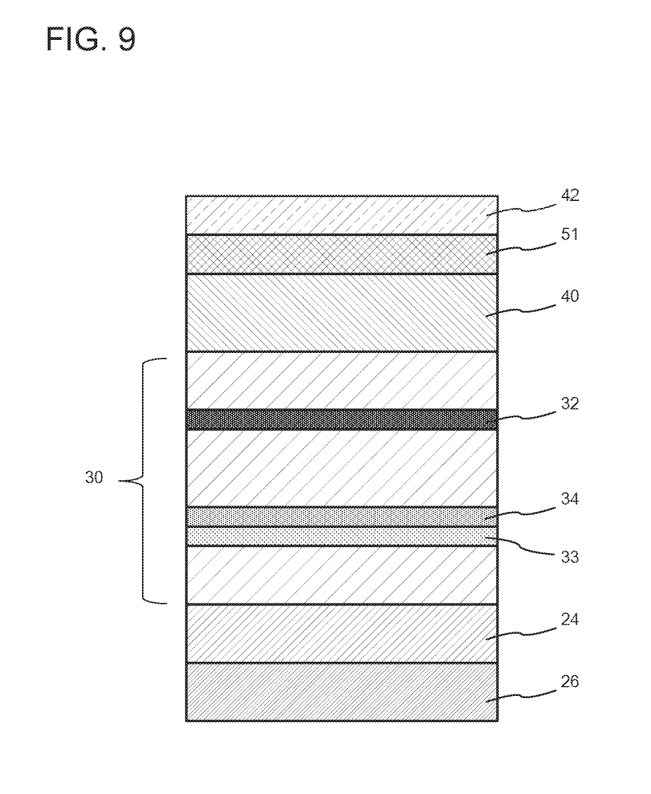

Next, the structure of the organic EL display device according to Embodiment 3 is explained using FIG. 9.

FIG. 9 is a schematic view of a cross section of the organic EL display device according to Embodiment 3 and is an expanded view of a portion with the organic layer 30 at the center. Unlike Embodiment 1, Embodiment 3 is characterized in that the red (R) light-emitting layer 33 and the green (G) light-emitting layer 34 are arranged instead of the Y light-emitting layer. Note that although the R light-emitting layer 33 and the G light-emitting layer 34 are arranged so as to be in contact with each other, some kind of organic material may be arranged between the R light-emitting layer 33 and the G light-emitting layer 34.

### <Variation of Embodiment 3>

In FIG. 9, a structure is illustrated in which the R light-emitting layer 33, the G light-emitting layer 34, and the B light-emitting layer 32 are arranged in this order from the side of the anode electrode. However, the order of the light-emitting layers may be different from this order. Further, although FIG. 9 shows a structure in which the photochromic layer 51 is arranged between the cathode electrode 40 and the passivation layer 42, the photochromic layer 52 (not shown) may be arranged between the anode electrode 24 and the reflective metal 26 as explained in Embodiment 2. Additionally, although the aforementioned photochromic layer 51 of Embodiment 1 has a property of selectively absorbing light of the B wavelength region, the photochromic layer 51 (or photochromic layer 52) may have a property of selectively absorbing light of the R wavelength region or the B wavelength region. Moreover, similar to the variation of Embodiment 2, both the photochromic layer 51 and the photochromic layer 52 may be included, and they may have a property of selectively absorbing light of different wavelength regions.

### Embodiment 4

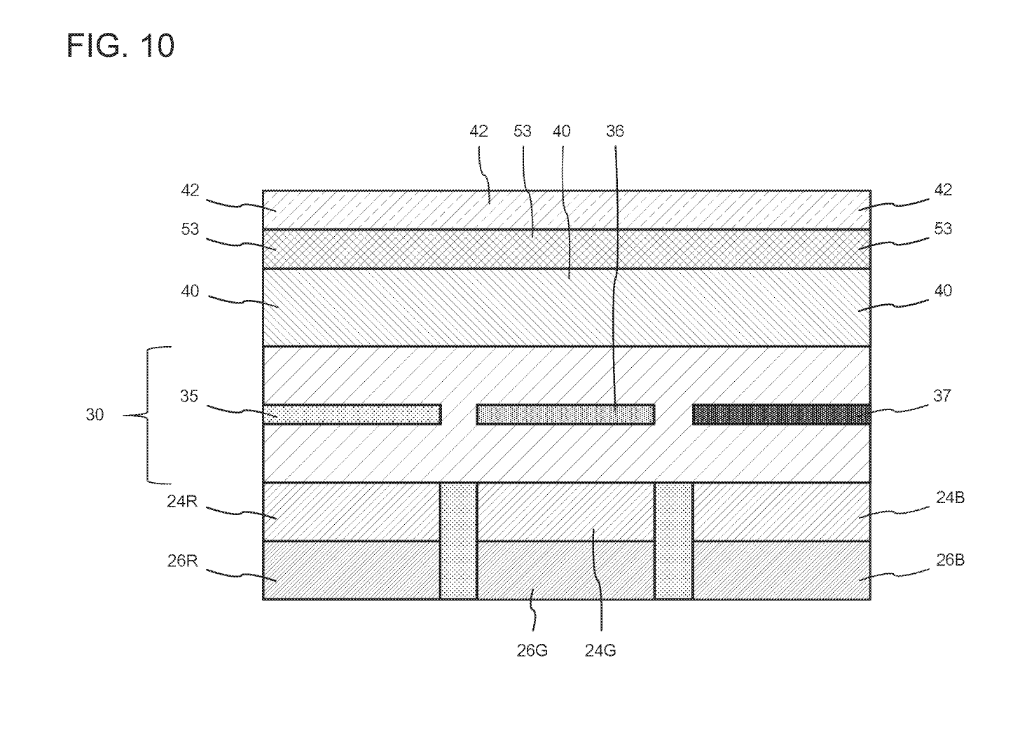

Next, the structure of the organic EL display device according to Embodiment 4 is explained with reference to FIG. 10.

FIG. 10 is a schematic view showing the layout of the light-emitting layer and the photochromic layer 53 of the organic EL display device according to Embodiment 4. FIG. 10 is a schematic view of adjacent three sub-pixels of R, G, and B, and the anode electrode 24R corresponding to the R sub-pixel, the anode electrode 24G corresponding to the G sub-pixel, the anode electrode 24B corresponding to the B sub-pixel are arranged. In Embodiment 4, the tandem structure explained in Embodiments 1 to 3 is not employed, but a structure of a SBS (side-by-side) mode is used in which the R light-emitting layer 35, the G light-emitting layer 36, and the B light-emitting layer 37 are arranged along a surface parallel to the substrate 20 (not shown). The photochromic layer 53 is arranged between the cathode electrode 40 and the passivation layer 42. Further, the photochromic layer 53 is formed on the whole surface so as to be substantially parallel to the substrate 20 similar to the cathode electrode 40.

Here, similar to the photochromic layer 51 explained in Embodiment 1, the photochromic layer 53 of Embodiment 4 selectively absorbs light of the B wavelength region (400 nm to 500 nm) and has a property whereby its transmittance decreases with an increasing amount of light irradiated thereto and increases with a decreasing amount of light irradiated thereto. Therefore, although the photochromic layer 53 is arranged on the upper side of the R light-emitting layer 35, the G light-emitting layer 36, and the B light-emitting layer 37, the photochromic layer 53 changes in transmittance only with respect to the light generated in the B light-emitting layer 37, but does not influence the light generated in the R light-emitting layer 35 and the G light-emitting layer 36. Thus, arrangement of the photochromic layer 53 in the organic EL display device having the SBS mode also provides the same effects explained in Embodiment 1.

In the aforementioned Embodiments, although the cases of the organic EL display device are described as exemplified disclosure, the embodiments can be applied to any kind of display devices of the flat panel type such as other self-emission type display devices, liquid crystal display devices, and electronic paper type display device having electrophoretic elements and the like. In addition, it is apparent that the size of the display device is not limited, and the embodiment can be applied to display devices having any size from medium to large.

The persons ordinarily skilled in the art are able to conceive of a variety of changes and modifications within the scope of the concept of the present invention, and the examples of such changes and modifications are also included in the scope of the invention. For example, a mode realized by the persons ordinarily skilled in the art through the appropriate addition, deletion, and design change of elements is included in the scope of the present invention as long as it possesses the concept of the present invention.

What is clamed is:

1. An organic EL display device comprising:
an insulating surface;
an anode electrode over the insulating surface;
an organic layer over the anode electrode;
a cathode electrode over the organic layer; and
a photochromic layer in contact with the cathode electrode or the anode electrode, the photochromic layer having a property of absorbing light of a specific wavelength region.

2. The organic EL display device according to claim 1,
wherein a transmittance of the photochromic layer decreases with an increasing amount of light irradiated to the photochromic layer and increases with a decreasing amount of light irradiated to the photochromic layer.

3. The organic EL display device according to claim 1,
wherein the organic layer has a tandem structure in which a plurality of light-emitting layers are stacked.

4. The organic EL display device according to claim 1,
wherein the photochromic layer is located over the cathode electrode.

5. The organic EL display device according to claim 1, further comprising a reflective metal layer between the insulating surface and the anode electrode,
wherein the photochromic layer is located between the reflective metal layer and the anode electrode.

6. The organic EL display device according to claim 1, further comprising a plurality of pixels,
wherein the organic layer is located in each of the plurality of pixels, and
wherein the photochromic layer is arranged so as to be shared by the plurality of pixels.

7. The organic EL display device according to claim 1,
wherein the photochromic layer includes a metal oxide including at least one of elements selected from Ti, V, Cr, Mn, Fe, Co, Ni, Cu, Zn, Nb, Mo, Ru, In, Sn, Sb, Ta, W, Re, Os, Ir, and Bi.

8. The organic EL display device according to claim 1,
wherein the photochromic layer includes one of a diarylethene compound, a spiropyran compound, a spiroperimidine compound, a viologen compound, and an azobenzene compound.

9. The organic EL display device according to claim 1,
wherein the diarylethene compound is a stilbene compound.

10. The organic EL display device according to claim 1,
wherein the photochromic layer has a light-absorbing property with respect to light of a wavelength region from 400 nm to 500 nm.
